(19) United States
(12) Patent Application Publication
(10) Pub. No.: US 2023/0207368 A1
(43) Pub. Date: Jun. 29, 2023

(54) BONDING APPARATUS AND BONDING METHOD

(71) Applicants: CANON KABUSHIKI KAISHA, Tokyo (JP); CANON MACHINERY INC., Kusatsu-shi (JP)

(72) Inventors: Kenichiro MORI, Tochigi (JP); Ryo SASAKI, Tochigi (JP); Takayuki HASEGAWA, Shiga (JP)

(21) Appl. No.: 18/057,817

(22) Filed: Nov. 22, 2022

(30) Foreign Application Priority Data
Nov. 25, 2021 (JP) 2021-191437

(51) Int. Cl. H01L 21/68; H01L 21/67

(52) U.S. Cl. CPC H01L 21/681; H01L 21/67144; H01L 21/67259; H01L 21/67092

(57) ABSTRACT

A bonding apparatus for bonding a second object to a first object, includes a first holder configured to hold the first object, a second holder configured to hold the second object, a positioning mechanism configured to change a relative position between the first holder and the second holder concerning a first direction and a second direction, a first camera configured to capture the first object, a second camera configured to capture the second object, a support configured to support the second holder and the first camera, and a controller configured to control the positioning mechanism concerning the first direction and the second direction based on an output of the first camera and an output of the second camera such that the second object is positioned to a bonding target portion of the first object.

### BACKGROUND OF THE INVENTION

### Field of the Invention

The present invention relates to a bonding apparatus and a bonding method.

### Description of the Related Art

Japanese Patent No. 6787612 describes an apparatus for positioning a first object with respect to a second object. The apparatus includes a moving body that linearly moves with respect to the second object. A holder configured to hold the first object and a position specifying means for specifying the position of the second object are attached to the moving body at a predetermined interval along the moving direction of the moving body. The apparatus further includes a scale arranged along the moving direction of the moving body. A first position detection unit configured to detect the position of the holder based on a graduation of the scale, and a second position detection unit configured to detect a graduation position of the scale corresponding to the position of the second object are attached to the moving body at the predetermined interval along the moving direction of the moving body. The apparatus further includes a controller configured to move the moving body to a position to detect the graduation position by the first position detection unit and position the first object with respect to the second object. According to the apparatus, even if the scale thermally expands, the first object can accurately be positioned with respect to the second object. In the apparatus, however, the moving direction of the moving body is one direction. Hence, the apparatus can only position the first object with respect to the second object at high accuracy only concerning the one direction.

### SUMMARY OF THE INVENTION

The present invention provides a technique advantageous in implementing positioning when bonding a second object to a predetermined portion of a first object at high accuracy concerning a first direction and a second direction.

One of aspects of the present invention provides a bonding apparatus for bonding a second object to a first object, comprising: a first holder configured to hold the first object; a second holder configured to hold the second object; a positioning mechanism configured to change a relative position between the first holder and the second holder concerning a first direction and a second direction; a first camera configured to capture the first object; a second camera configured to capture the second object; a support configured to support the second holder and the first camera; and a controller configured to control the positioning mechanism concerning the first direction and the second direction based on an output of the first camera and an output of the second camera such that the second object is positioned to a bonding target portion of the first object.

Further features of the present invention will become apparent from the following description of exemplary embodiments with reference to the attached drawings.

### BRIEF DESCRIPTION OF THE DRAWINGS

FIG. 1 is a view schematically showing the configuration of a bonding apparatus according to the first embodiment;

FIG. 2 is a view showing an example of the configuration of a wafer stage in the bonding apparatus according to the first embodiment;

FIG. 3 is a flowchart showing a bonding method in the bonding apparatus according to the first embodiment;

FIG. 4 is a flowchart showing a method of calculating the offset of a die bonding position in the bonding apparatus according to the first embodiment;

FIG. 5 is a view schematically showing the configuration of a bonding apparatus according to the second embodiment;

FIG. 6 is a view showing an example of the configuration of a wafer stage in the bonding apparatus according to the second embodiment;

FIG. 7 is a view schematically showing the configuration of a bonding apparatus according to the third embodiment;

FIG. 8 is a view showing an example of the configuration of a bonding stage in the bonding apparatus according to the third embodiment;

FIG. 9 is a view schematically showing the configuration of a bonding apparatus according to the fourth embodiment;

FIG. 10 is a view showing an example of the configuration of a bonding stage in the bonding apparatus according to the fourth embodiment; and

FIG. 11 is a view schematically showing the configuration of a bonding apparatus according to the fifth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following explanation, a first object will be described as a wafer on which a semiconductor device is formed, and a second object will be described as a separated die including a semiconductor device. However, the first object and the second object are not limited to these, and various changes and modifications can be made within the scope of the present invention.

For example, the first object may be a silicon wafer, a silicon wafer on which wirings are formed, a glass wafer, a glass panel on which wirings are formed, an organic panel (PCB) on which wirings are formed, or a metal panel. Alternatively, the first object may be a substrate obtained by bonding a die on which a semiconductor device is formed to a wafer on which a semiconductor device is formed.

For example, the second object may be a structure made by stacking several separated dies, or a structure such as a small piece of a material, an optical element, or a MEMS.

The bonding method is not limited to a specific bonding method. For example, the bonding method may be bonding using an adhesive, temporary bonding using a temporary adhesive, bonding by hybrid bonding, atomic diffusion bonding, vacuum bonding, bump bonding, or the like, and various temporary bonding or permanent bonding methods can be used.

Industrial application examples will be described here. The first application example is manufacturing of a stacked memory. In the application to manufacturing of a stacked memory, the first object can be a wafer on which a memory is formed, and the second object can be a memory serving as a separated die. Normally, eight layers are stacked. Hence, in bonding of the eighth layer, the first object can be a substrate in which six layers of memories are already bonded onto a wafer. Note that the final layer may be a driver configured to drive the memories.

The second application example is heterogeneous integration for a processor. The mainstream of a conventional processor is an SoC formed by incorporating a logic circuit and an SRAM in one semiconductor chip. On the other hand, elements are formed on separate wafers by applying optimum processes and bonded to manufacture a processor. This can implement cost reduction and yield improvement of processors. In the application to heterogeneous integration, the first object can be a wafer on which a logic device that is a semiconductor device is formed, and the second object can be a die of an SRAM, an antenna, or a driver separated after probing. Normally, different dies are sequentially bonded. Hence, in the first object, bonded objects sequentially increase. For example, in a case where bonding is started from an SRAM, when bonding the element next to the SRAM, a structure made by bonding the SRAM to a logic wafer is the first object. Note that when bonding a plurality of dies, as for the order of bonding, bonding is preferably started from a thin die such that a bonding head does not interfere with a bonded die.

The third application example is 2.5D bonding using a silicon interposer. The silicon interposer is a silicon wafer on which wirings are formed. The 2.5D bonding is a method of bonding separated dies using the silicon interposer, thereby electrically bonding the dies. In the application to die bonding to the silicon interposer, the first object may be a silicon wafer on which wirings are formed, and the second object may be a separated die. Normally, a plurality of types of dies are bonded to the silicon interposer. Hence, the first object also includes a silicon interposer to which several dies are already bonded. Note that when bonding a plurality of dies, as for the order of bonding, bonding is preferably started from a thin die such that a bonding head does not interfere with a bonded die.

The fourth application example is 2.1D bonding using an organic interposer or a glass interposer. The organic interposer is an organic panel (a PCB substrate or a CCL substrate) used as a package substrate, on which wirings are formed, and the glass interposer is a glass panel on which wirings are formed. The 2.1D bonding is a method of bonding separated dies to the organic interposer or the glass interposer, thereby electrically bonding the dies by the wirings on the interposer. In the application to die bonding to the organic interposer, the first object may be an organic panel on which wirings are formed. In the application to die bonding to the glass interposer, the first object may be a glass panel on which wirings are formed. The second object may be a separated die. Normally, a plurality of types of dies are bonded to the organic interposer or the glass interposer. Hence, the first object also includes an organic interposer or a glass interposer to which several dies are already bonded. Note that when bonding a plurality of dies, as for the order of bonding, bonding is preferably started from a thin die such that a bonding head does not interfere with a bonded die.

The fifth application example is temporary bonding in a fan-out package manufacturing process. There is known fan-out wafer-level packaging that reconstructs separated dies into a wafer shape using a mold resin to do packaging. There is also known fan-out panel-level packaging that reconstructs separated dies into a panel shape to do packaging. In the packaging, rewirings from the dies to bumps are formed, or rewirings that bond different types of dies are formed on a molded reconstructed substrate. At this time, if the die array accuracy is low, when transferring the rewiring pattern using a step-and-repeat exposure apparatus, the rewiring pattern cannot accurately be aligned to the dies. For this reason, the dies are required to be arranged at a high array accuracy. In the application to the fan-out package manufacturing process, the first object may be a substrate such as a metal panel to be temporarily bonded, and the second object may be a separated die. The separated dies can be temporarily bonded to the substrate such as a metal panel by a temporary adhesive. After that, the separated dies are molded into a wafer shape or a panel shape by a molding apparatus, and peeled from the substrate such as a metal panel after molding, thereby manufacturing a reconstructed wafer or a reconstructed panel. In the application to this bonding, the bonding position by the bonding apparatus is preferably adjusted to correct an array deformation caused by the molding process.

The sixth application example is heterogeneous substrate bonding. For example, in the field of infrared image sensors, InGaAs is known as a high sensitivity material. If InGaAs is used for a sensor unit configured to receive light, and silicon capable of implementing high-speed processing is used for a logic circuit configured to extract data, a high-sensitivity high-speed infrared image sensor can be manufactured. However, from InGaAs crystal, only wafers whose diameter is as small as 4 inches are mass-produced, which is smaller than a mainstream silicon wafer having a size of 300 mm. Hence, a method of bonding a separated InGaAs substrate to a 300-mm silicon wafer on which a logic circuit is formed has been proposed. The bonding apparatus can also be applied to heterogeneous substrate bonding for bonding substrates made of different materials and having different sizes. In the application to heterogeneous substrate bonding, the first object may be a substrate such as a silicon wafer with a large diameter, and the second object may be a small piece of a material such as InGaAs. Note that the small piece of the material is a slice of a crystal. The piece is preferably cut into a rectangular shape.

### First Embodiment

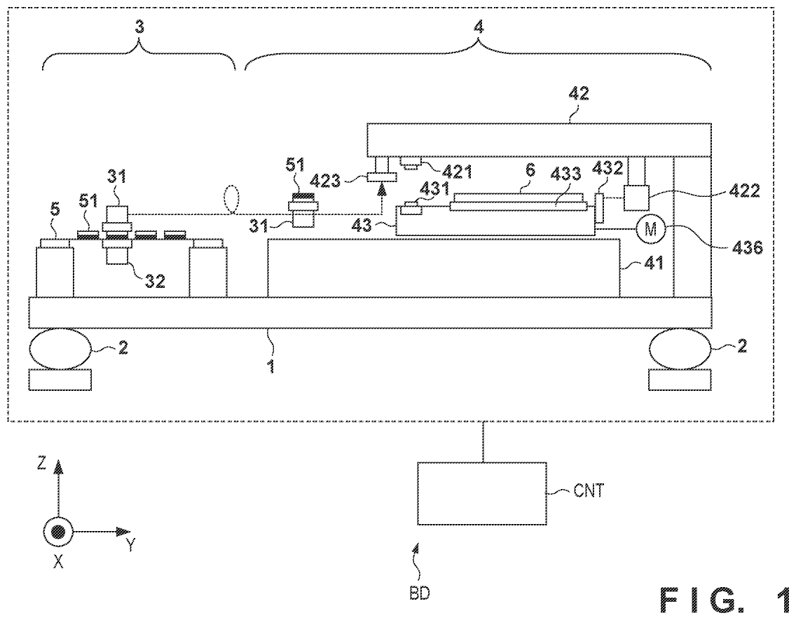

FIG. 1 is a view schematically showing the configuration of a bonding apparatus BD according to the first embodiment. In FIG. 1, directions are indicated by an XYZ coordinate system. Typically, an XY plane is a plane parallel to the horizontal plane, and a Z-axis is an axis parallel to the vertical direction. X-, Y-, and Z-axes are examples of directions that are orthogonal to each other or cross each other. This also applies to the other drawings.

As shown in FIG. 1, the bonding apparatus BD can include a pickup unit 3 and a bonding unit 4, which are arranged on a base 1 damped by mounts 2. FIG. 1 shows an example in which the pickup unit 3 and the bonding unit 4 are mounted on one base 1. However, the pickup unit 3 and the bonding unit 4 may individually be mounted on separate bases. The bonding apparatus BD can be configured to position and bond a die 51 as a second object to a bonding target portion on a wafer 6 as a first object. The die 51 can be provided while being held by a dicing tape put on a dicing frame 5. The bonding apparatus BD can also include a controller CNT that controls the pickup unit 3 and the bonding unit 4. The controller CNT can be formed by, for example, a PLD (short for Programmable Logic Device) such as an FPGA (short for Field Programmable Gate Array), an ASIC (short for Application Specific Integrated Circuit), or a general-purpose or dedicated computer with a program installed, or a combination of all or some of the above-described devices.

The pickup unit 3 can include a pickup head 31 and a release head 32. The pickup unit 3 can peel the die 51 to be bonded to the wafer 6 from the dicing tape by the release head 32 and hold the die 51 by the pickup head 31 sucking. The pickup head 31 can, for example, rotate the die 51 by 180° and transfer it to a bonding head 423 of the bonding unit 4. The pickup head 31 can contact the bonding surface of the die 51. Hence, in an application example to a bonding method of performing bonding by activating the surface, like hybrid bonding, it is preferable to form, as the surface that comes into contact with the bonding surface, a highly stable surface with a diamond like carbon (DLC) coating or a fluorine coating, or reduce the contact area by forming pin shapes with a high density and with a small contact area. Alternatively, a noncontact handling method like a Bernoulli chuck or a method of preventing contact with the bonding surface by holding a side surface or an edge portion may be used.

The bonding unit 4 can include a stage base 41 and an upper base 42. A wafer stage 43 serving as a first holder can be mounted on the stage base 41. The wafer stage 43 can be driven in the x-axis direction (first direction) and the y-axis direction (second direction) by a driving mechanism 436 such as a linear motor. The driving mechanism 436 may be configured to further drive the wafer stage 43 concerning the rotation about an axis parallel to the z-axis direction (third direction). Instead of driving the wafer stage 43 by the driving mechanism 436 concerning the rotation about the axis parallel to the z-axis direction, the bonding head 423 may drive the die 51 concerning the rotation about the axis parallel to the z-axis direction. The driving mechanism 436 can form a positioning mechanism that changes the relative position between a wafer chuck 433 (or the wafer 6) serving as the first holder and the bonding head 423 (or the die 51) serving as a second holder.

A die observation camera 431 serving as a second camera can be mounted on the wafer stage 43. The die observation camera 431 is a second detector configured to detect the position of a featured portion of the die 51 as the second object held by the bonding head 423. A bar mirror 432 is provided on the wafer stage 43. The bar mirror 432 can be used as the target of an interferometer 422. The wafer chuck 433 serving as the first holder can be mounted on the wafer stage 43. The wafer chuck 433 holds the wafer 6 as the first object.

In the example shown in FIG. 1, the wafer stage 43 functions as a support structure that supports the wafer chuck 433 serving as the first holder and the die observation camera 431 serving as the second camera. The wafer stage 43 serving as the support structure can include a first end face (the left end face in FIG. 1) on the side of a path to convey the die 51 as the second object to the bonding head 423 as the second holder, and a second end face (the right end face in FIG. 1) on the opposite side of the first end face. The die observation camera 431 as the second camera can be arranged between the first end face and a virtual plane that passes through the center of the support structure and is parallel to the first end face. Alternatively, in another viewpoint, the die observation camera 431 as the second camera can be arranged between a predetermined position in the path to convey the die 51 as the second object to the bonding head 423 as the second holder and the wafer chuck 433 as the first holder. This configuration is advantageous in decreasing the amount of driving the wafer stage 43 to observe the die 51 held by the bonding head 423 by the die observation camera 431 and thus improving throughput.

A wafer observation camera 421 serving as a first camera can be mounted on the upper base 42. The wafer observation camera 421 is a first detector configured to detect the position of a featured portion of the wafer 6 as the first object held by the wafer chuck 433. The controller CNT can be configured to specify or calculate the positions of a plurality of bonding target portions on the wafer 6 based on the position of the featured portion of the wafer 6 detected using the wafer observation camera 421. The interferometer 422 configured to measure the position of the wafer stage 43 using the bar mirror 432 can further be mounted on the upper base 42. Also, the bonding head 423 that receives and holds the die 51 as the second object transferred from the pickup head 31 and bonds the die 51 to the bonding target portion of the wafer 6 can be mounted on the upper base 42. The bonding head 423 also has a function as the second holder that holds the die 51 as the second object.

In the example shown in FIG. 1, the upper base 42 is a support, and the support is configured to support the bonding head 423 serving as the second holder and the wafer observation camera 421 serving as the first camera. The upper base 42 serving as the support can include a third end face (the left end face in FIG. 1) on the side of the path to convey the die 51 as the second object to the bonding head 423 as the second holder, and a fourth end face (the right end face in FIG. 1) on the opposite side of the third end face. The wafer observation camera 421 as the first camera can be arranged between the third end face and a second virtual plane that passes through the center of the support and is parallel to the third end face. This configuration is advantageous in decreasing the amount of driving the wafer stage 43 to observe the wafer 6 held by the wafer chuck 433 by the wafer observation camera 421 and thus improving throughput.

When bonding the die 51 as the second object to the bonding target portion of the wafer 6 as the first object, the bonding head 423 drives the die 51 in the negative direction (downward) of the Z-axis, thereby bonding the die 51 to the bonding target portion of the wafer 6. Alternatively, the driving mechanism 436 drives the wafer stage 43 in the positive direction (upward) of the Z-axis, thereby bonding the die 51 to the bonding target portion of the wafer 6. Alternatively, a driving mechanism (not shown) drives the wafer chuck 433 in the positive direction (upward) of the Z-axis, thereby bonding the die 51 to the bonding target portion of the wafer 6.

In the above description, the pickup head 31 rotates the die 51 by 180° and transfers it to the bonding head 423. However, a first die holder and a second die holder may be provided, the die 51 may be transferred from the first die holder to the second die holder in the midway, and the die 51 may then be transferred from the second die holder the bonding head 423. Alternatively, a driving mechanism that drives the bonding head 423 may be provided, and the bonding head 423 may be driven such that the bonding head 423 receives the die 51. Also, to improve productivity, a plurality of pickup units, a plurality of pickup heads, a plurality of release heads, and a plurality of bonding heads may be provided.

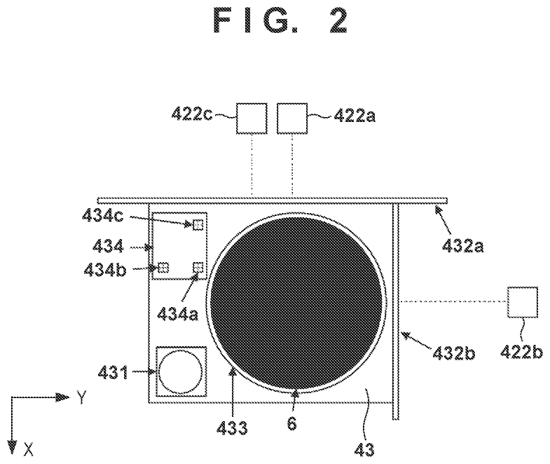

FIG. 2 is a view showing the wafer stage 43 viewed from the positive direction of the Z-axis. The wafer 6 is held by the wafer chuck 433. The wafer 6 or the wafer stage 43 can be positioned concerning the x-axis direction (first direction) and the y-axis direction (second direction), which are orthogonal to each other or cross each other, and the rotation about an axis parallel to the z-axis direction (third direction) orthogonal to these. To do this, the wafer stage 43 can be provided with the bar mirror 432, more specifically, bar mirrors 432a and 432b. The bar mirror 432a can function as the target of interferometers 422a and 422c. The controller CNT can detect the position of the wafer stage 43 in the x-axis direction based on the output of the interferometer 422a, and can also detect rotation of the wafer stage 43 about the axis parallel to the z-axis direction based on the outputs of the interferometers 422a and 422c. The bar mirror 432b can function as the target of an interferometer 422b. The controller CNT can detect the position of the wafer stage 43 in the y-axis direction based on the output of the interferometer 422b. The controller CNT can be configured to feedback-control the wafer 6 or the wafer stage 43 based on the outputs of the interferometers 422a, 422b, and 422c concerning the x-axis direction, the y-axis direction, and the rotation about the axis parallel to the z-axis direction orthogonal to these. The interferometers 422 and the controller CNT may be understood as the constituent elements of the above-described positioning mechanism.

A reference plate 434 can be provided on the upper surface of the wafer stage 43. A plurality of marks 434a, 434b, and 434c can be arranged on the reference plate 434. The reference plate 434 is made of a material with a low thermal expansion coefficient, and the marks can be drawn at a high position accuracy. In an example, the reference plate 434 can be formed by drawing marks on a quartz substrate using the drawing method of a semiconductor lithography process. The reference plate 434 has a surface with almost the same height as the surface of the wafer 6, and can be observed by the wafer observation camera 421. A camera used to observe the reference plate 434 may separately be provided. The wafer stage 43 can have a configuration that combines a coarse motion stage that is driven within a large range, and a fine motion stage that is accurately driven within a small range. In this configuration, the die observation camera 431, the bar mirrors 432a and 432b, the wafer chuck 433, and the reference plate 434 can be provided on the fine motion stage to implement accurate positioning.

A method of guaranteeing the origin position, the magnification, and the directions (rotations) and orthogonality of the X-axis and the Y-axis of the wafer stage 43 using the reference plate 434 will be described here. The mark 434a is observed by the wafer observation camera 421, and the output value of the interferometer when the mark 434a is located at the center of the output image of the wafer observation camera 421 is defined as the origin of the wafer stage 43. Next, the mark 434b is observed by the wafer observation camera 421, and the direction (rotation) of the Y-axis of the wafer stage 43 and the magnification in the y-axis direction are decided based on the output value of the interferometer when the mark 434b is located at the center of the output image of the wafer observation camera 421. Next, the mark 434c is observed by the wafer observation camera 421, and the direction (rotation) of the X-axis of the wafer stage 43 and the magnification in the x-axis direction are decided based on the output value of the interferometer when the mark 434c is located at the center of the output image of the wafer observation camera 421.

That is, defining the direction from the mark 434b of the reference plate 434 to the mark 434a as the Y-axis of the bonding apparatus BD, and the direction from the mark 434c to the mark 434a as the X-axis of the bonding apparatus BD, the directions and orthogonality of the axes can be calibrated. Also, defining the interval between the mark 434b and the mark 434a as the scale reference of the Y-axis of the bonding apparatus BD and the interval between the mark 434c and the mark 434a as the scale reference of the X-axis of the bonding apparatus BD, calibration can be performed. Since the refractive index of the optical path of the interferometer changes due to variations of the atmospheric pressure and temperature, and this makes the measured value vary, it is preferable to perform calibration at an arbitrary timing and guarantee the origin position, the magnification, the rotation, and the orthogonality of the wafer stage 43. To reduce the variation of the measured value of the interferometer, it is preferable to cover, with a temperature control chamber, the space in which the wafer stage 43 is arranged and control the temperature in the temperature control chamber.

Note that, in this embodiment, a form in which the reference plate on the wafer stage is observed by the wafer observation camera has been described. Even if the reference plate is attached to the upper base and observed by the die observation camera, the origin position, the magnification, the rotation, and the orthogonality of the wafer stage can be guaranteed.

The above explanation is related to an example in which calibration is performed by observing the reference plate. Instead, for example, calibration may be performed by an abutting operation to a reference surface, or accurate positioning may be performed using a position measurement device such as a white interferometer that guarantees an absolute value.

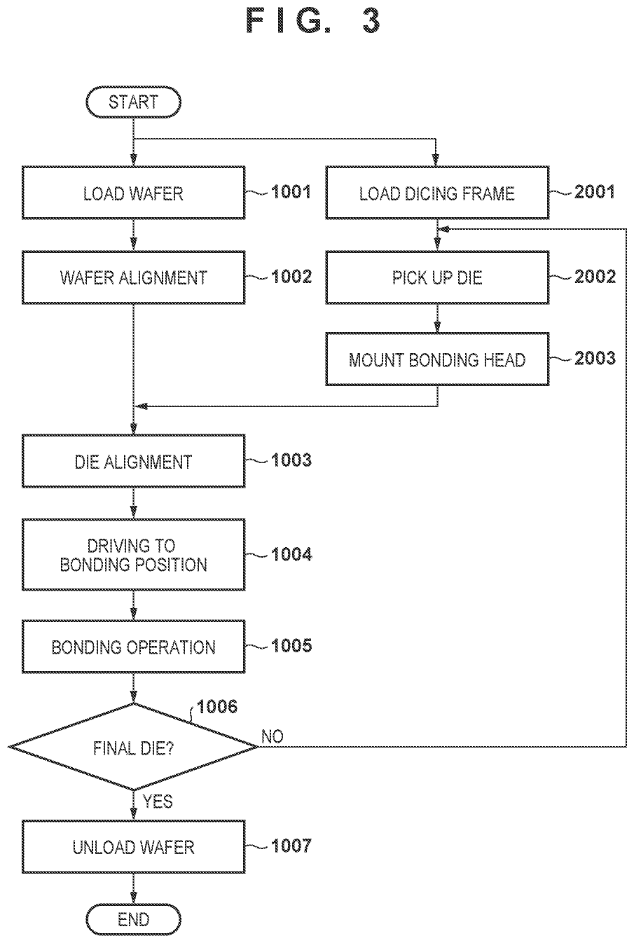

A bonding method according to the first embodiment will be described below with reference to the flowchart of FIG. 3. This bonding method is controlled by the controller CNT. In step 1001, the wafer 6 as the first object is loaded into the bonding apparatus BD and held by the wafer chuck 433 (first holding step). Since adhesion of a foreign substance to the bonding surface causes a bonding failure, the space in the bonding apparatus BD can be kept at a high cleanliness of, for example, class 1. To keep a high cleanliness, the wafer 6 can be stored in a container such as a FOUP that has a high airtightness and maintains a high cleanliness and loaded from the container into the bonding apparatus BD. Also, to increase the cleanliness, the wafer 6 may be washed in the bonding apparatus BD after loading. Preprocessing for bonding can be also be executed. For example, in bonding using an adhesive, processing of adhering the adhesive to the wafer 6 can be executed. In hybrid bonding, processing of activating the surface of the wafer 6 can be executed. The wafer 6 is coarsely positioned by a prealigner (not shown) based on a notch or an orientation flat and a wafer outer shape position, conveyed to the wafer chuck 433 serving as the first holder on the wafer stage 43, and held by the wafer chuck 433.

In step 1002, the position of a featured portion (measurement target portion) of the wafer 6 is measured using the wafer observation camera 421, and the position of a bonding target portion is decided based on it. Here, the positional relationship (relative position) between the featured portion (measurement target portion) of the wafer 6 and the bonding target portion is known. Focus adjustment performed to capture the featured portion of the wafer 6 by the wafer observation camera 421 can be provided by providing a focus adjustment mechanism in the wafer observation camera 421. Alternatively, focus adjustment may be provided by providing a Z-axis driving mechanism in the wafer stage 43 and driving the wafer 6 concerning the Z-axis by the Z-axis driving mechanism. In many cases, an alignment mark for alignment is formed on the wafer 6. If no alignment mark is formed, a featured portion whose position can be specified can be measured. The controller CNT can cause the wafer observation camera 421 to capture the featured portion of the wafer 6 (first image capturing step) and detect the relative position of the image of the featured portion with respect to the center of the output image of the wafer observation camera 421 as the position of the featured portion (measurement target portion).

To accurately measure the relative position of a mark with respect to the reference point of the bonding apparatus BD, an offset amount may be obtained in advance. This can include processing of driving the wafer stage 43 to make the mark of the reference plate 434 fall within the visual field of the wafer observation camera 421 and measuring the position of the mark by the wafer observation camera 421. Based on the driving position of the wafer stage 43 at that time and the position of the mark measured using the wafer observation camera 421, the offset amount with respect to the position measured using the wafer observation camera 421 can be decided. Here, in general, the reference point of the bonding apparatus BD is often a specific mark position of the reference plate 434. However, another place may be set if it is a position serving as a reference.

Since the measurement range of a rotation direction by an interferometer or an encoder is narrow, a rotation amount that can be corrected by the wafer stage 43 is small. For this reason, if the rotation amount of the wafer 6 is large, it is preferable to correct the rotation and hold the wafer 6 again. If the wafer 6 is held again, the mounting position of the wafer 6 needs to be measured again. Also, during this operation, the surface position of the bonding surface of the wafer 6 may be measured in the auto-focus operation at the time of measurement of the mark on the wafer or using a first height measurement device (not shown). Since the thickness of the wafer 6 varies, measuring the surface position of the wafer 6 is advantageous in accurately managing the gap between the wafer 6 and the die 51 in the bonding operation.

Since the origin position, the magnification, and the directions (rotations) and orthogonality of the X-axis and the Y-axis of the wafer stage 43 are guaranteed using the reference plate 434, the position of the featured portion (measurement target portion) of the wafer 6 can be measured based on the origin position and the X-axis and the Y-axis of the wafer stage 43. The wafer 6 can have bonding target portions (or semiconductor devices as a bonding target) at a predetermined period. These bonding target portions (semiconductor devices) are manufactured by accurately positioning a plurality of layers in a semiconductor manufacturing apparatus. Hence, the bonding target portions (semiconductor devices) are repetitively arrayed generally at a period with a nano-level accuracy. For this reason, in wafer alignment of step 1002, it is not necessary to measure the positions of featured portions corresponding to all the bonding target portions (semiconductor devices). The controller CNT can be configured to measure the positions of measurement target portions in number smaller than the number of bonding target portions and statistically process the measurement result, thereby executing processing of deciding the positions of a plurality of bonding target portions (first measurement step). Such control is advantageous in improving throughput as compared to the method disclosed in Japanese Patent No. 6787612 in which a bonding portion is measured in every die bonding. Here, the plurality of measurement target portions can be decided based on the array information of semiconductor devices. To decide the positions of the plurality of bonding target portions, the controller CNT can calculate the origin position of the repetitive array of the plurality of bonding target portions, the rotation amounts and orthogonality of the directions of the X-axis and the Y-axis, and the magnification error of the repetitive period based on the measurement result of the positions of the plurality of measurement target portions.

In addition, the wafer chuck 433 preferably has a temperature control function of controlling the temperature of the wafer 6. This is because in a case where the thermal expansion coefficient of a silicon wafer is 3 ppm/° C., and the diameter of the wafer is 300 mm, if the temperature increases by 1° C., the position of the outermost periphery moves by 150 mm×0.000003=0.00045 mm=450 nm. If a bonding position moves after wafer alignment, bonding cannot be performed at a high position accuracy. It is therefore preferable to stabilize the temperature of the wafer at an accuracy of 0.1° C. or less.

If the first object is an interposer on which wirings are formed, the plurality of bonding target portions are decided based on not the array of semiconductor devices but the array of the repetitively formed wirings. If the first object is a wafer or panel without a pattern, the wafer alignment in step 1002 is not executed.

The movement of the die as the second object, which is executed in parallel to or after the loading of the wafer as the first object and wafer alignment will be described below. In step 2001, the dicing frame 5 on which the dies 51 separated by a dicer are arrayed on a dicing tape is loaded into the bonding apparatus BD. Here, since adhesion of a foreign substance to the bonding surface causes a bonding failure, the dicing frame can be conveyed using a container that has a high airtightness and maintains a high cleanliness. Also, to increase the cleanliness, the dies 51 on the dicing frame 5 may be washed in the bonding apparatus BD. The rotation direction and the shift position of the dicing frame 5 can coarsely be decided by a prealigner (not shown) based on the outer shape of the dicing frame.

In step 2002, the die 51 as the second object is picked up by the pickup head 31. More specifically, the pickup head 31 and the release head 32 can be positioned at the position of the die 51 to be picked up. While the die 51 to be picked up is sucked by the pickup head 31, the dicing tape is peeled from the die 51 by the release head 32, and the die 51 can be held by the pickup head 31. The die 51 to be picked up can be decided based on, for example, non-defective die (KGD: Known Good Die) information transmitted to the bonding apparatus BD online. Normally, only non-defective dies are picked up. However, when bonding a defective die (KBD: Known Bad Die) to the portion of a defective device of the wafer 6, a defective die is picked up.

In step 2003, the die 51 as the second object picked up by the pickup head 31 is conveyed to the bonding head 423 and held by the bonding head 423 (second holding step). When the die 51 is picked up by the pickup head 31, the semiconductor device surface faces the pickup head 31. On the other hand, the die 51 is conveyed to the bonding head 423 such that the face on the opposite side of the semiconductor device surface faces the bonding head 423. The conveyance of the die 51 to the bonding head 423 may be done directly by the pickup head 31 to the bonding head 423 or may be done via a plurality of die holders. Also, preprocessing for bonding may be executed during the conveyance of the die 51. The preprocessing can include, for example, die washing processing, processing of applying an adhesive in bonding using an adhesive, or processing of activating the surface in hybrid bonding. Note that if surface activity becomes inactive during the conveyance of the die 51 to the bonding head 423, processing of activating the bonding surface is preferably performed using an atmospheric pressure plasma activation apparatus after the die 51 is mounted on the bonding head 423.

Thus, a state in which the wafer 6 as the first object and the die 51 as the second object are held by the holders therefor is obtained. A bonding procedure will be described next. In step 1003, the position of the die 51 as the second object held by the bonding head 423 can be measured (second measurement step). More specifically, the wafer stage 43 can be driven by the driving mechanism 436 to make the featured portion of the die 51 fall within the visual field of the die observation camera 431. Focus adjustment may be provided by providing a focus adjustment mechanism in the die observation camera 431, or may be provided by providing a Z-axis driving mechanism in the bonding head 423 and driving the die 51 concerning the Z-axis by the Z-axis driving mechanism. Alternatively, focus adjustment may be provided by providing a Z-axis driving mechanism in the wafer stage 43 on which the die observation camera 431 is mounted and driving the die observation camera 431 concerning the Z-axis by this.

A scribe line on which an alignment mark used for alignment in a semiconductor manufacturing step is formed can be removed by dicing. Hence, the die 51 does not include an alignment mark for alignment in many cases. For this reason, a terminal portion of an array of pads or bumps arranged on the die 51, a region which has an aperiodic array and whose position can be specified, or the outer shape of the die can be defined as a featured portion, and its position can be measured. The controller CNT can cause the die observation camera 431 to capture the die 51 (second image capturing step) and decide the position of the featured portion based on the relative position of the image of the featured portion with respect to the center of the output image of the die observation camera 431. An offset amount when positioning the die 51 to the bonding portion needs to be managed based on the position of the die 51 measured using the die observation camera 431. A method for this will be described later.

When measuring the position of the die 51, it is preferable to measure the positions of a plurality of featured portions in the die 51 and measure the rotation amount of the die 51 as well. To measure the positions of the plurality of featured portions, the wafer stage 43 may be driven every time the position of each featured portion is measured, or the visual field of the die observation camera 431 may be designed to observe the plurality of featured portions at once. The die 51 can be rotated by rotating the wafer stage 43 at the time of bonding. The measurement range of a rotation direction by an interferometer is narrow. For this reason, if the rotation amount of the die 51 is large, it is preferable to correct the rotation and hold the die 51 again. If the die 51 is held again, the position of the die 51 needs to be measured again. Also, during this operation, the surface position of the bonding surface of the die 51 as the second object may be measured in the auto-focus operation at the time of measurement of the position of the die or using a second height measurement device (not shown). Since the thickness of the die 51 varies, measuring the surface position of the die 51 is advantageous in accurately managing the gap between the wafer 6 and the die 51 in the bonding operation. Also, heights at a plurality of positions on the die 51 may be measured, and the posture of the die 51 or the wafer 6 may be adjusted by a tilt mechanism (not shown) at the time of bonding. This tilt mechanism can be incorporated in the wafer stage 43, the wafer chuck 433, or the bonding head 423.

In step 1004, the wafer stage 43 is driven by the driving mechanism 436 such that the die 51 as the second object is positioned to a bonding target portion selected from the plurality of bonding target portions of the wafer 6 as the first object. At this time, the controller CNT can control the driving mechanism 436 such that the position of the wafer stage 43 is feedback-controlled based on the measurement result of the interferometer 422. Also, at this time, the controller CNT can decide the target position of the wafer stage 43 based on the position and the rotation amount of the wafer 6 and the position and the rotation amount of the die 51, which are measured in steps 1002 and 1003, and the offset amount. If a shift occurs due to the bonding operation, as will be described later, the controller CNT takes this into consideration as an offset amount.

In step 1005, the die 51 as the second object is bonded to the selected bonding target portion of the wafer 6 as the first object (bonding step). As an operation for bonding, the bonding head 423 may be lifted/lowered, or the wafer stage 43 or the wafer chuck 433 may be lifted/lowered. To prevent the positioning accuracy from becoming low at the time of lifting/lowering, lifting/lowering can be performed by employing a lifting driving system with high reproducibility or while continuing feedback control. To perform lifting/lowering while continuing feedback control, when lifting/lowering the wafer stage 43, the width of the bar mirror in the z-axis direction is designed such that the bar mirror is not deviated from the optical path of the interferometer even during lifting/lowering. On the other hand, when lifting/lowering the bonding head 423 or the wafer chuck 433, feedback control is performed while monitoring the position deviations of the bonding head 423 or the wafer chuck 433 in the x- and y-axis directions using an encoder or a gap sensor. To accurately control the gap between the first object and the second object, a linear encoder may be provided to measure the z-axis direction position of the lifting driving mechanism. Also, if the first object and the second object come into contact with each other, the wafer stage that is feedback-controlled using the interferometer is restrained. Hence, the control method may be changed before and after contact by, for example, stopping feedback control. Processing until bringing the die 51 into contact with the bonding target portion of the wafer 6 has been described above. In bump bonding, a step necessary for bonding, such as a step of pressing the die 51 against the wafer 6 at a predetermined pressing pressure and a step of observing the bonding state after bonding can be added.

If bonding of one die 51 to the wafer 6 is ended, in step 1006, the controller CNT determines whether the dies 51 as the second objects are bonded to all the plurality of bonding target portions of the wafer 6 as the first object. Normally, several tens to several hundreds of semiconductor devices are arranged on one wafer 6. Since the die 51 is bonded to each of the semiconductor devices, bonding of the die 51 is repeated a plurality of times. If bonding of the dies 51 to all the plurality of bonding target portions of the wafer 6 is not ended, the process returns to die pickup in step 2002. Note that in the example shown in FIG. 3, the above-described determination is performed after the bonding operation in step 1005, and the die 51 is picked up in step 2002. However, the die pickup in step 2002 may be executed in parallel from die alignment in step 1003 to the bonding operation in step 1005. Also, when bonding a plurality of types of dies to one semiconductor device, after bonding of dies of one type to all semiconductor devices in one wafer 6 is ended, bonding of dies of the next type can be started. In this case, in the die pickup of step 2002, a die of the next type is picked up. At this time, a step such as an operation of loading a dicing frame on which dies of the next type are mounted is executed.

If bonding of the dies 51 to all the plurality of bonding target portions of the wafer 6 is ended, in step 1007, the wafer 6 is unloaded from the bonding apparatus BD. The wafer 6 may be returned to the loaded FOUP or may be returned to another container. In general, however, the thickness of the wafer changes due to bonding. Since the gap between wafers needs to be extended as compared to wafers before bonding, the wafer 6 is returned to another container.

The bonding procedure of the plurality of second objects to one first object has been described above. The operation is repeated for a necessary number of first objects. Note that since the number of dies on the dicing frame and the number of semiconductor devices on the wafer to which the dies are bonded are generally different, loading of the wafer and the loading of the dicing frame do not synchronize. If dies on the dicing frame run out during bonding of dies to one wafer, the next dicing frame is loaded. Also, if dies on the dicing frame remain even after the end of bonding of dies to all semiconductor devices on one wafer, those dies are used for bonding to the next wafer.

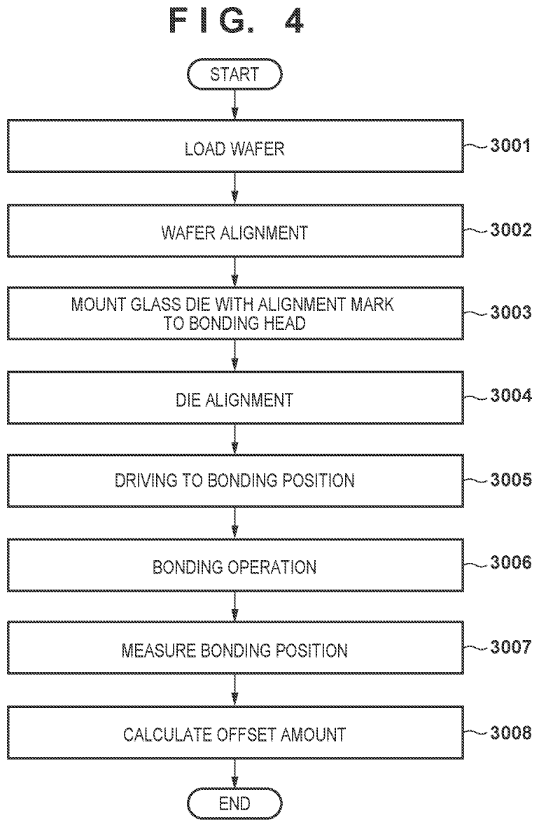

A method of managing the offset amount reflected in bonding position driving of step 1004 on the position of the die 51 measured using the die observation camera 431 will be described next with reference to the flowchart of FIG. 4. Processing shown in the flowchart of FIG. 4 is controlled by the controller CNT.

In step 3001, the wafer 6 as the first object is loaded into the bonding apparatus BD and held by the wafer chuck 433. An alignment mark used for alignment of the wafer 6 and a mark used to measure a bonding deviation to be described later are formed on the wafer 6. Also, the wafer 6 can be prepared such that a position deviation of the die 51 does not occur after mounting of the die 51 by a method of, for example, arranging a temporary adhesive at the bonding target portion. The wafer 6 is coarsely positioned by a prealigner (not shown) based on a notch or an orientation flat and a wafer outer shape position, conveyed to the wafer chuck 433 serving as the first holder on the wafer stage 43, and held by the wafer chuck 433.

In step 3002, the position of the alignment mark on the wafer 6 is measured using the wafer observation camera 421, and the mounting position and the rotation amount of the wafer 6 are calculated based on the result. Also, during this operation, the surface position of the bonding surface of the wafer 6 may be measured using a first height measurement device (not shown). Since the thickness of the wafer 6 varies, measuring the surface position of the wafer 6 is advantageous in accurately managing the gap between the wafer 6 and the die 51 in the bonding operation.

In step 3003, a glass die with an alignment mark is held by the bonding head 423. The glass die is used to confirm a bonding deviation using the wafer observation camera 421 after bonding. Hence, the die is made of a material that passes light of a wavelength to be detected by the wafer observation camera 421. For example, if observation is performed using infrared light, a silicon die may be used. An alignment mark used to measure the position of the die and a mark used to measure a bonding deviation are formed on the die.

In step 3004, the position and the rotation amount of the glass die with an alignment mark, which is held by the bonding head 423, are measured. Also, during this operation, the surface position of the bonding surface of the glass die with an alignment mark may be measured using a second height measurement device (not shown). Since the thickness of the glass die with an alignment mark varies, measuring the surface position of the glass die with an alignment mark is advantageous in accurately managing the gap between the wafer 6 and the die 51 in the bonding operation. Also, heights at a plurality of positions on the glass die with an alignment mark may be measured, and the posture of the die 51 or the wafer 6 may be adjusted by a tilt mechanism (not shown) at the time of bonding. This tilt mechanism can be incorporated in the wafer stage 43, the wafer chuck 433, or the bonding head 423.

In step 3005, the wafer stage 43 is driven by the driving mechanism 436 such that the glass die with an alignment mark is positioned to a bonding target portion selected from the plurality of bonding target portions of the wafer 6. At this time, the controller CNT can control the driving mechanism 436 such that the position of the wafer stage 43 is fed back based on the measurement result of the interferometer 422. Also, at this time, the controller CNT can decide the target position of the wafer stage 43 based on the position and the rotation amount of the wafer 6 and the position and the rotation amount of the glass die with an alignment mark, which are measured in steps 3002 and 3004, and the offset amount.

In step 3006, the glass die with an alignment mark is bonded to the selected bonding target portion of the wafer 6, as in step 1005.

In step 3007, the bonding position is measured. More specifically, the wafer stage 43 is driven by the driving mechanism 436 such that the mark used to measure the bonding deviation falls within the visual field of the wafer observation camera 421, and the bonding deviation amount between the wafer 6 and the glass die is measured using the wafer observation camera 421. Examples of the mark used to measure the bonding deviation are a rectangular frame having a width of 30 μm on the wafer side and a rectangular frame having a width of 60 μm on the glass die side. Bonding is performed such that the two frames overlap, and the bonding deviation can be calculated from the deviation amount between the two frames. The mark used to measure the bonding deviation may be not a rectangle but a circle. The mark on the wafer side may be an outer mark, and the mark on the die side may be an inner mark. Two different marks may be measured, and the deviation amount may be detected from the interval therebetween. To decide the bonding deviation, the deviation amount may be measured for each of marks on a plurality of portions in the glass die. If the measurement is performed for the marks on the plurality of portions in the glass die, the rotation error of bonding can also be measured. In addition, it is possible to reduce the measurement error by statistic processing and accurately measure the bonding deviation.

In step 3008, the controller CNT calculates the offset amount based on the position deviation measured using the die observation camera 431. The calculated offset amount can include, for example, the shift amounts in the x-axis direction and the y-axis direction and the rotation amount about the axis in the z-axis direction. Here, a glass die may be bonded to each of the plurality of bonding target portions of the wafer 6, and the offset amount may be calculated for each of the plurality of bonding target portions. Alternatively, a glass die may be bonded to each of the plurality of bonding target portions of the wafer 6, and offset amounts calculated for the plurality of bonding target portions may be averaged to calculate the final offset amount.

An example of positioning when bonding the die to the wafer using the measurement results of the positions of the wafer and the die and the offset amount decided in advance will be described below. Note that although signs are inverted depending on the manner the directions of coordinates are defined, the following example complies with the coordinate system shown in the drawings. Let (Wx, Wy) be the position of the wafer 6 measured in step 1002 (the position with respect to the reference point of the bonding apparatus BD), and Wθ be the rotation amount. Also, let (Dx, Dy) be the position of the die 51 with respect to the center of the image captured in step 1003, and Dθ be the rotation amount. Let (Px, Py) be the shift amount generated at the time of bonding, and Pθ be the rotation amount. Also, let (X0, Y0) and θ0 be the offset amounts obtained in step 3008.

If the offset amounts in step 3008 are correctly obtained, Wx=Wy=Wθ=Dx=Dy=Dθ=0. If the same process as in step 3008 is used, bonding can be performed at a high accuracy by driving the wafer stage 43 to (X0, Y0) and θ0 and performing bonding.

If the position of the wafer 6 is deviated from the reference of the wafer stage 43, for example, deviated in the positive direction, this can be corrected by moving the wafer stage 43 by the same amount in the negative direction. Hence, in bonding, the wafer stage 43 is driven to (X0−Wx, Y0−Wy) and (θ0−Wθ).

On the other hand, if the position of the die 51 is deviated from the reference of the bonding head 423, for example, deviated in the positive direction, this can be corrected by moving the wafer stage 43 by the same amount in the positive direction. Hence, to adjust the bonding position, in bonding, the wafer stage 43 is driven to (X0−Wx+Dx, Y0−Wy+Dy), and (θ0−Wθ+Dθ).

Furthermore, as for the shift amount generated at the time of bonding, the bonding position can be adjusted by performing a shift in the same amount. Hence, if deviation occurs in the positive direction, bonding is performed after moving the wafer stage 43 by the same amount. Hence, in bonding, the wafer stage 43 is driven to (X0−Wx+Dx+Px, Y0−Wy+Dy+Py) and (θ0−Wθ+Dθ+Pθ).

### Second Embodiment

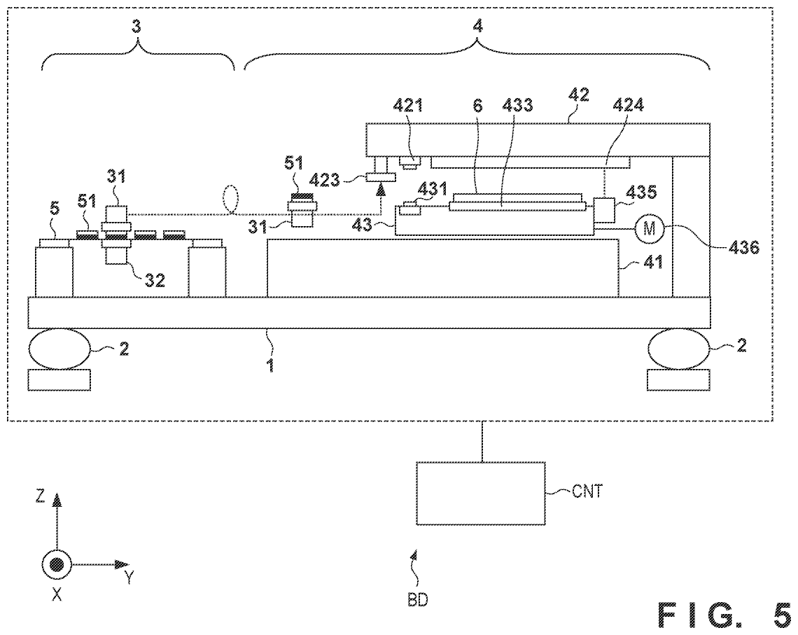

The second embodiment will be described below. Matters that are not mentioned as the second embodiment can comply with the first embodiment. FIG. 5 is a view schematically showing the configuration of a bonding apparatus BD according to the second embodiment. In the bonding apparatus BD according to the second embodiment, the position of a wafer stage 43 is measured using an encoder.

More specifically, in place of the interferometer 422 and the bar mirror 432 in the bonding apparatus BD according to the first embodiment, an encoder scale 424 and an encoder head 435 are employed in the bonding apparatus BD according to the second embodiment. The encoder head 435 is a two-dimensional encoder head mounted on the wafer stage 43. The encoder scale 424 is a two-dimensional encoder scale mounted on an upper base 42. The encoder scale 424 has a two-dimensional scale such that the position of the wafer stage 43 can be measured in the movable range of the wafer stage 43. The encoder head 435 measures the position of the wafer stage 43 concerning the x-axis direction and the y-axis direction.

The encoder scale 424 is made of a material with a low thermal expansion coefficient, and the scale can be drawn at a high position accuracy. In an example, the encoder scale 424 can be formed by drawing the scale on a quartz substrate using the drawing method of a semiconductor lithography process. The wafer stage 43 can have a configuration in which a fine motion stage that is accurately driven within a small range is mounted on a coarse motion stage that is driven within a large range. In this configuration, the encoder head 435 can be provided on the fine motion stage to perform accurate positioning. A controller CNT can be configured to feedback-control a wafer 6 or the wafer stage 43 based on the output of the encoder head 435 concerning the x-axis direction, the y-axis direction, and the rotation about an axis parallel to the z-axis direction orthogonal to these. A driving mechanism 436 can form a positioning mechanism that changes the relative position between the wafer stage 43 (or the wafer 6) serving as a first holder and a bonding head 423 (or a die 51) serving as a second holder. The encoder head 435 and the controller CNT may be understood as the constituent elements of the positioning mechanism.

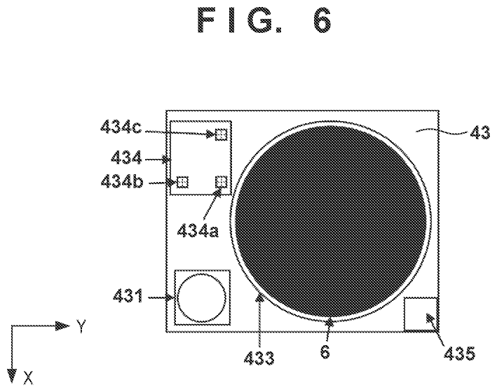

FIG. 6 is a view showing the wafer stage 43 viewed from the positive direction of the Z-axis. A method of guaranteeing the origin position, the magnification, and the directions (rotations) and orthogonality of the X-axis and the Y-axis of the wafer stage 43 using a reference plate 434 will be described with reference to FIG. 6. A mark 434a is observed by a wafer observation camera 421, and the output value of the encoder head 435 when the mark 434a is located at the center of the output image of the wafer observation camera 421 is defined as the origin of the wafer stage 43. Next, a mark 434b is observed by the wafer observation camera 421, and the direction (rotation) of the Y-axis of the wafer stage 43 and the magnification in the y-axis direction are decided based on the output value of the encoder head 435 when the mark 434b is located at the center of the output image of the wafer observation camera 421. Next, a mark 434c is observed by the wafer observation camera 421, and the direction (rotation) of the X-axis of the wafer stage 43 and the magnification in the x-axis direction are decided based on the output value of the encoder head 435 when the mark 434c is located at the center of the output image of the wafer observation camera 421. That is, defining the direction from the mark 434b of the reference plate 434 to the mark 434a as the Y-axis of the bonding apparatus BD, and the direction from the mark 434c to the mark 434a as the X-axis of the bonding apparatus BD, the directions and orthogonality of the axes can be calibrated. Also, defining the interval between the mark 434b and the mark 434a as the scale reference of the Y-axis of the bonding apparatus BD and the interval between the mark 434c and the mark 434a as the scale reference of the X-axis of the bonding apparatus BD, calibration can be performed. Since the encoder scale 424 is expanded by heat, and this makes the value measured by the encoder head 435 vary, it is preferable to perform calibration at an arbitrary timing and guarantee the origin position, the magnification, the rotation, and the orthogonality of the wafer stage 43. Note that instead of employing the two-dimensional encoder, a linear encoder may be employed concerning each of the X-axis and the Y-axis.

In place of the above-described configuration, a plurality of encoder heads may be arranged, and, for example, the plurality of encoder heads may selectively be used in accordance with the position of the bonding target portion. This configuration is advantageous in reducing foot print. Alternatively, a pair of encoder heads may be arranged to be symmetrical with respect to the bonding target portion. This configuration is advantageous in improving position measurement accuracy.

The above explanation is related to an example in which calibration is performed by observing the reference plate. Instead, for example, calibration may be performed by an abutting operation to a reference surface, or a calibration mechanism may be provided in the encoder and used as a position measurement device that guarantees an absolute value.

### Third Embodiment

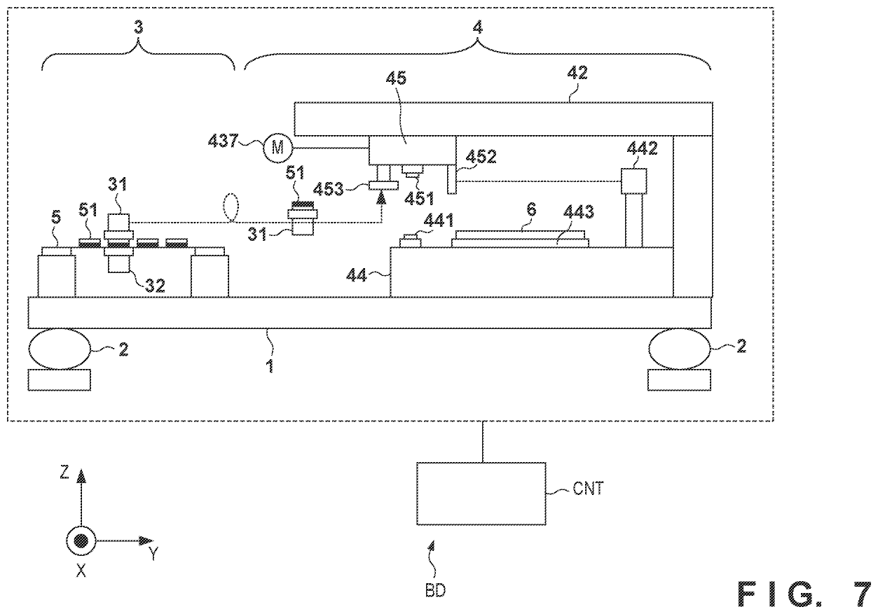

The third embodiment will be described below. Matters that are not mentioned as the third embodiment can comply with the first embodiment. FIG. 7 is a view schematically showing the configuration of a bonding apparatus BD according to the third embodiment. In the bonding apparatus BD according to the third embodiment, a bonding head 453 is positioned, thereby changing or adjusting the relative position between a wafer 6 as a first object and a die 51 as a second object.

A bonding unit 4 can include an upper base 42 and a lower base 44. A bonding stage 45 can be supported by the upper base 42. The bonding stage 45 can be driven concerning the x-axis direction (first direction) and the y-axis direction (second direction) by a driving mechanism 437 such as a linear motor. The driving mechanism 437 may be configured to further drive the bonding stage 45 concerning the rotation about an axis parallel to the z-axis direction (third direction). Instead of driving the bonding stage 45 by the driving mechanism 437 concerning the rotation about the axis parallel to the z-axis direction, a wafer chuck 443 may be driven concerning the rotation about the axis parallel to the z-axis direction. The driving mechanism 437 can form a positioning mechanism that changes the relative position between the wafer chuck 443 (or the wafer 6) serving as a first holder and a bonding head 453 (or the die 51) serving as a second holder.

A wafer observation camera 451 serving as a first camera can be mounted on the bonding stage 45. The wafer observation camera 451 is a first detector configured to detect the position of a featured portion of the wafer 6 as the first object held by the wafer chuck 443. Also, the bonding head 453 as the second holder that receives and holds the die 51 as the second object transferred from a pickup head 31 and bonds the die 51 to the bonding target portion of the wafer 6 can be mounted on the bonding stage 45. In the example shown in FIG. 7, the bonding stage 45 can form a support that supports the bonding head 453 serving as the second holder and the wafer observation camera 451 serving as the first camera. A bar mirror 452 can be provided on the bonding stage 45. The bar mirror 452 can be used as the target of an interferometer 442.

A die observation camera 441 serving as a second camera can be mounted on the lower base 44. The die observation camera 441 is a second detector configured to detect the position of a featured portion of the die 51 as the second object held by the bonding head 453. The wafer chuck 443 serving as the first holder can be mounted on the lower base 44. The wafer chuck 443 holds the wafer 6 as the first object. The interferometer 442 configured to measure the position of the bonding stage 45 using the bar mirror 452 can further be mounted on the lower base 44. In the example shown in FIG. 7, the lower base 44 functions as a support structure that supports the wafer chuck 443 serving as the first holder and the die observation camera 441 serving as the second camera.

When bonding the die 51 as the second object to the bonding target portion of the wafer 6 as the first object, the bonding head 453 drives the die 51 in the negative direction (downward) of the Z-axis, thereby bonding the die 51 to the bonding target portion of the wafer 6. Alternatively, the driving mechanism 437 drives the bonding stage 45 in the negative direction (downward) of the Z-axis, thereby bonding the die 51 to the bonding target portion of the wafer 6. Alternatively, a driving mechanism (not shown) drives the wafer chuck 443 in the positive direction (upward) of the Z-axis, thereby bonding the die 51 to the bonding target portion of the wafer 6.

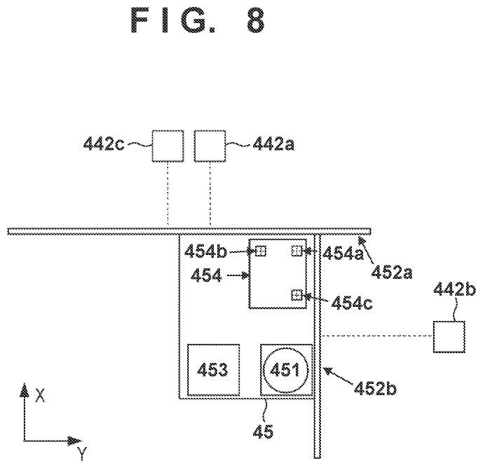

FIG. 8 is a view showing the bonding stage 45 viewed from the negative direction of the Z-axis. The bonding head 453 holds the die 51. The die 51 can be positioned concerning the x-axis direction (first direction) and the y-axis direction (second direction), which are orthogonal to each other or cross each other, and the rotation about an axis parallel to the z-axis direction (third direction) orthogonal to these. To do this, the bonding stage 45 can be provided with the bar mirror 452, more specifically, bar mirrors 452a and 452b. The bar mirror 452a can function as the target of interferometers 442a and 442c. A controller CNT can detect the position of the bonding stage 45 in the x-axis direction based on the output of the interferometer 442a, and can also detect rotation of the bonding stage 45 about the axis parallel to the z-axis direction based on the outputs of the interferometers 442a and 442c. The bar mirror 452b can function as the target of an interferometer 442b. The controller CNT can detect the position of the bonding stage 45 in the y-axis direction based on the output of the interferometer 442b. The controller CNT can be configured to feedback-control the die 51 or the bonding stage 45 based on the outputs of the interferometers 442a, 442b, and 442c concerning the x-axis direction, the y-axis direction, and the rotation about the axis parallel to the z-axis direction orthogonal to these. The interferometers 442 and the controller CNT may be understood as the constituent elements of the above-described positioning mechanism.

A reference plate 454 is provided on the lower surface of the bonding stage 45. A plurality of marks 454a, 454b, and 454c are arranged on the reference plate 454. The reference plate 454 is made of a material with a low thermal expansion coefficient, and the marks can be drawn at a high position accuracy. In an example, the reference plate 454 can be formed by drawing marks on a quartz substrate using the drawing method of a semiconductor lithography process. The reference plate 454 has a surface with almost the same height as the surface of the die 51, and can be observed by the die observation camera 441. A camera used to observe the reference plate 454 may separately be provided. The bonding stage 45 can have a configuration that combines a coarse motion stage that is driven within a large range, and a fine motion stage that is accurately driven within a small range. In this configuration, the wafer observation camera 451, the bar mirrors 452a and 452b, the bonding head 453, and the reference plate 454 can be provided on the fine motion stage to implement accurate positioning.

A method of guaranteeing the origin position, the magnification, and the directions (rotations) and orthogonality of the X-axis and the Y-axis of the bonding stage 45 using the reference plate 454 will be described here. The mark 454a is observed by the die observation camera 441, and the output value of the interferometer when the mark 454a is located at the center of the output image of the die observation camera 441 is defined as the origin of the bonding stage 45. Next, the mark 454b is observed by the die observation camera 441, and the direction (rotation) of the Y-axis of the bonding stage 45 and the magnification in the y-axis direction are decided based on the output value of the interferometer when the mark 454b is located at the center of the output image of the die observation camera 441. Next, the mark 454c is observed by the die observation camera 441, and the direction (rotation) of the X-axis of the bonding stage 45 and the magnification in the x-axis direction are decided based on the output value of the interferometer when the mark 454c is located at the center of the output image of the die observation camera 441.

That is, defining the direction from the mark 454b of the reference plate 454 to the mark 454a as the Y-axis of the bonding apparatus BD, and the direction from the mark 454c to the mark 454a as the X-axis of the bonding apparatus BD, the directions and orthogonality of the axes can be calibrated. Also, defining the interval between the mark 454b and the mark 454a as the scale reference of the Y-axis of the bonding apparatus BD and the interval between the mark 454c and the mark 454a as the scale reference of the X-axis of the bonding apparatus BD, calibration can be performed. Since the refractive index of the optical path of the interferometer changes due to variations of the atmospheric pressure and temperature, and this makes the measured value vary, it is preferable to perform calibration at an arbitrary timing and guarantee the origin position, the magnification, the rotation, and the orthogonality of the bonding stage 45. To reduce the variation of the measured value of the interferometer, it is preferable to cover, with a temperature control chamber, the space in which the bonding stage 45 is arranged and control the temperature in the temperature control chamber.

In this embodiment, a form in which the reference plate on the bonding stage is observed by the die observation camera has been described. Instead, even if the reference plate is attached to the lower base and observed by the wafer observation camera, the origin position, the magnification, the rotation, and the orthogonality of the bonding stage can be guaranteed.

The above explanation is related to an example in which calibration is performed by observing the reference plate. Instead, for example, calibration may be performed by an abutting operation to a reference surface, or accurate positioning may be performed using a position measurement device such as a white interferometer that guarantees an absolute value.

In the third embodiment, since the position to perform bonding and the portion measured by the interferometer are apart, an Abbe error is preferably corrected. In addition, the error may be reduced by performing measurement on both sides across the bonding stage.

A bonding procedure according to the third embodiment will be described below with reference to the flowchart of FIG. 3. The bonding procedure is controlled by the controller CNT. In step 1001, the wafer 6 as the first object is loaded into the bonding apparatus BD and held by the wafer chuck 443. The wafer 6 is coarsely positioned by a prealigner (not shown) based on a notch or an orientation flat and a wafer outer shape position, conveyed to the wafer chuck 443 serving as the first holder on the lower base 44, and held by the wafer chuck 443.

In step 1002, the mounting position of the wafer 6 is measured using the wafer observation camera 451. Focus adjustment may be provided by providing a focus adjustment mechanism in the wafer observation camera 451, or by providing a Z-axis driving mechanism in the wafer chuck 443 and driving the wafer 6 concerning the Z-axis by the Z-axis driving mechanism. Alternatively, focus adjustment may be provided by providing a Z-axis driving mechanism in the bonding stage 45 and driving the wafer observation camera 451 concerning the Z-axis by the Z-axis driving mechanism. In many cases, an alignment mark for alignment is formed on the wafer 6. If no alignment mark is formed, a featured portion whose position can be specified can be measured. The controller CNT can detect the relative position of the image of the featured portion with respect to the center of the output image of the wafer observation camera 451 as the position of the featured portion.

To accurately measure the relative position of a mark with respect to the reference point of the bonding apparatus BD, an offset amount may be obtained in advance. This can include processing of driving the bonding stage 45 to make the mark of the reference plate 454 fall within the visual field of the wafer observation camera 451 and measuring the position of the mark by the wafer observation camera 451. The offset amount with respect to the position measured using the wafer observation camera 451 can be decided based on the driving position of the bonding stage 45 at that time. Here, in general, the reference point of the bonding apparatus BD is often a specific mark position of the reference plate 454. However, another place may be set if it is a position serving as a reference.

Since the measurement range of a rotation direction by an interferometer is narrow, a rotation amount that can be corrected by the bonding stage 45 is small. For this reason, if the rotation amount of the wafer 6 is large, it is preferable to correct the rotation and hold the wafer 6 again. If the wafer 6 is held again, the mounting position of the wafer 6 needs to be measured again. Also, during this operation, the surface position of the bonding surface of the wafer 6 may be measured using a first height measurement device (not shown). Since the thickness of the wafer 6 varies, measuring the surface position of the wafer 6 is advantageous in accurately managing the gap between the wafer 6 and the die 51 in the bonding operation.

Since the origin position, the magnification, and the directions (rotations) and orthogonality of the X-axis and the Y-axis of the bonding stage 45 are guaranteed using the reference plate 454, the position of the mounted wafer 6 is measured based on the origin position and the X-axis and the Y-axis of the bonding stage 45.

The movement of the die as the second object, which is executed in parallel to or after the loading of the wafer as the first object and wafer alignment will be described below. In step 2001, a dicing frame 5 on which the dies 51 separated by a dicer are arrayed on a dicing tape is loaded into the bonding apparatus BD. In step 2002, the die 51 as the second object is picked up by the pickup head 31.

In step 2003, the die 51 as the second object picked up by the pickup head 31 is conveyed to the bonding head 453. When the die 51 is picked up by the pickup head 31, the semiconductor device surface faces the pickup head 31. On the other hand, the die 51 is conveyed to the bonding head 453 such that the face on the opposite side of the semiconductor device surface faces the bonding head 453. The conveyance of the die 51 to the bonding head 453 may be done directly by the pickup head 31 to the bonding head 453 or may be done via a plurality of die holders. Also, preprocessing for bonding can be executed during the conveyance of the die 51. The preprocessing can include, for example, die washing processing, processing of applying an adhesive in bonding using an adhesive, or processing of activating the surface in hybrid bonding. Note that if surface activity becomes inactive during the conveyance of the die 51 to the bonding head 453, processing of activating the bonding surface is preferably performed using an atmospheric pressure plasma activation apparatus after the die 51 is mounted on the bonding head 453.

Thus, a state in which the wafer 6 as the first object and the die 51 as the second object are held by the holders therefor is obtained. A bonding procedure will be described next. In step 1003, the position of the die 51 as the second object held by the bonding head 453 can be measured. More specifically, the bonding stage 45 can be driven by the driving mechanism 437 to make the featured portion of the die 51 fall within the visual field of the die observation camera 441. Focus adjustment may be provided by providing a focus adjustment mechanism in the die observation camera 441, or may be provided by providing a Z-axis driving mechanism in the bonding head 453 and driving the die 51 concerning the Z-axis by the Z-axis driving mechanism.

A scribe line on which an alignment mark used for alignment in a semiconductor manufacturing step is formed can be removed by dicing. Hence, the die 51 does not include an alignment mark for alignment in many cases. For this reason, a terminal portion of an array of pads or bumps arranged on the die 51, a region which has an aperiodic array and whose position can be specified, or the outer shape of the die can be defined as a featured portion, and its position can be measured. The controller CNT can decide the position of the featured portion based on the relative position of the image of the featured portion with respect to the center of the output image of the die observation camera 441. An offset amount when positioning the die 51 to the bonding portion needs to be managed based on the position of the die 51 measured using the die observation camera 441. A method for this will be described later.

When measuring the position of the die 51, it is preferable to measure the positions of a plurality of featured portions in the die 51 and measure the rotation amount of the die 51 as well. To measure the positions of the plurality of featured portions, the bonding stage 45 may be driven every time the position of each featured portion is measured, or the visual field of the die observation camera 441 may be designed to observe the plurality of featured portions at once. The die 51 can be rotated by rotating the bonding stage 45 at the time of bonding. The measurement range of a rotation direction by an interferometer is narrow. For this reason, if the rotation amount of the die 51 is large, it is preferable to correct the rotation and hold the die 51 again. If the die 51 is held again, the position of the die 51 needs to be measured again. Also, during this operation, the surface position of the bonding surface of the die 51 as the second object may be measured using a second height measurement device (not shown). Since the thickness of the die 51 varies, measuring the surface position of the die 51 is advantageous in accurately managing the gap between the wafer 6 and the die 51 in the bonding operation. Also, heights at a plurality of positions on the die 51 may be measured, and the posture of the die 51 or the wafer 6 may be adjusted by a tilt mechanism (not shown) at the time of bonding. This tilt mechanism can be incorporated in the wafer chuck 443 or the bonding head 453.

In step 1004, the bonding stage 45 is driven by the driving mechanism 437 such that the die 51 as the second object is positioned to a bonding target portion selected from the plurality of bonding target portions of the wafer 6 as the first object. At this time, the controller CNT can control the driving mechanism 437 such that the bonding stage 45 is feedback-controlled based on the measurement result of the interferometer 442. Also, at this time, the controller CNT can decide the position of the bonding stage 45 based on the position and the rotation amount of the wafer 6 and the position and the rotation amount of the die 51, which are measured in steps 1002 and 1003, and the offset amount. If a shift occurs due to the bonding operation, as will be described later, the controller CNT takes this into consideration as an offset amount.

In step 1005, the die 51 as the second object is bonded to the selected bonding target portion of the wafer 6 as the first object. As an operation for bonding, the bonding stage 45 or the bonding head 453 may be lifted/lowered, or the wafer chuck 443 may be lifted/lowered. To prevent the positioning accuracy from becoming low at the time of lifting/lowering, lifting/lowering can be performed by employing a lifting driving system with high reproducibility or while continuing feedback control. To perform lifting/lowering while continuing feedback control, when lifting/lowering the bonding stage 45, the width of the bar mirror in the z-axis direction is designed such that the bar mirror is not deviated from the optical path of the interferometer even during lifting/lowering. On the other hand, when lifting/lowering the bonding head 453 or the wafer chuck 443, feedback control is performed while monitoring the position deviations of the bonding head 453 or the wafer chuck 443 in the x- and y-axis directions using an encoder or a gap sensor. To accurately control the gap between the first object and the second object, a linear encoder may be provided to measure the z-axis direction position of the lifting driving mechanism. Also, if the first object and the second object come into contact with each other, the bonding stage 45 that is feedback-controlled using the interferometer is restrained. Hence, the control method may be changed before and after contact by, for example, stopping feedback control. Processing until bringing the die 51 into contact with the bonding target portion of the wafer 6 has been described above. In bump bonding, a step necessary for bonding, such as a step of pressing the die 51 against the wafer 6 at a predetermined pressing pressure and a step of observing the bonding state after bonding can be added.

Processing from step 1006 is the same as in the first embodiment, and a description thereof will be omitted.

A method of managing the offset amount reflected in bonding position driving of step 1004 on the position of the die 51 measured using the die observation camera 441 will be described next with reference to the flowchart of FIG. 4. Processing shown in the flowchart of FIG. 4 is controlled by the controller CNT.

In step 3001, the wafer 6 as the first object is loaded into the bonding apparatus BD and held by the wafer chuck 443. A mark used for alignment of the wafer 6 and a mark used to measure a bonding deviation are formed on the wafer 6. Also, the wafer 6 can be prepared such that a position deviation of the die 51 does not occur after mounting of the die 51 by a method of, for example, arranging a temporary adhesive at the bonding target portion. The wafer 6 is coarsely positioned by a prealigner (not shown) based on a notch or an orientation flat and a wafer outer shape position, conveyed to the wafer chuck 443 serving as the first holder on the lower base 44, and held by the wafer chuck 443.

In step 3002, the position of the alignment mark on the wafer 6 is measured using the wafer observation camera 451, and the mounting position and the rotation amount of the wafer 6 are calculated based on the result. Also, in this operation, the surface position of the bonding surface of the wafer 6 may be measured using a first height measurement device (not shown). Since the thickness of the wafer 6 varies, measuring the surface position of the wafer 6 is advantageous in accurately managing the gap between the wafer 6 and the die 51 in the bonding operation.

In step 3003, a glass die with an alignment mark is held by the bonding head 453. The glass die is used to confirm a bonding deviation using the wafer observation camera 451 after bonding. Hence, the die is made of a material that passes light of a wavelength to be detected by the wafer observation camera 451. For example, if observation is performed using infrared light, a silicon die may be used. An alignment mark used to measure the position of the die and a mark used to measure a bonding deviation are formed on the die.

In step 3004, the position and the rotation amount of the glass die with an alignment mark, which is held by the bonding head 453, are measured. Also, during this operation, the surface position of the bonding surface of the glass die with an alignment mark may be measured using a second height measurement device (not shown). Since the thickness of the glass die with an alignment mark varies, measuring the surface position of the glass die with an alignment mark is advantageous in accurately managing the gap between the wafer 6 and the die 51 in the bonding operation. Also, heights at a plurality of positions on the glass die with an alignment mark may be measured, and the posture of the die 51 or the wafer 6 may be adjusted by a tilt mechanism (not shown) at the time of bonding. This tilt mechanism can be incorporated in the wafer chuck 443 or the bonding head 453.

In step 3005, the bonding stage 45 is driven by the driving mechanism 437 such that the glass die with an alignment mark is positioned to a bonding target portion selected from the plurality of bonding target portions of the wafer 6. At this time, the controller CNT can control the driving mechanism 437 such that the position of the bonding stage 45 is fed back based on the measurement result of the interferometer 442. Also, at this time, the controller CNT can decide the target position of the bonding stage 45 based on the position and the rotation amount of the wafer 6 and the position and the rotation amount of the glass die with an alignment mark, which are measured in steps 3002 and 3004, and the offset amount.

In step 3006, the glass die with an alignment mark is bonded to the selected bonding target portion of the wafer 6, as in step 1005.

In step 3007, the bonding position is measured. More specifically, the bonding stage 45 is driven by the driving mechanism 437 such that the mark used to measure the bonding deviation falls within the visual field of the wafer observation camera 451, and the bonding deviation amount between the wafer 6 and the glass die is measured using the wafer observation camera 451.

In step 3008, the controller CNT calculates the offset amount based on the position deviation measured using the wafer observation camera 451. The calculated offset amount can include, for example, the shift amounts in the x-axis direction and the y-axis direction and the rotation amount about the axis in the z-axis direction. Here, a glass die may be bonded to each of the plurality of bonding target portions of the wafer 6, and the offset amount may be calculated for each of the plurality of bonding target portions. Alternatively, a glass die may be bonded to each of the plurality of bonding target portions of the wafer 6, and offset amounts calculated for the plurality of bonding target portions may be averaged to calculate the final offset amount.

An example of positioning when bonding the die to the wafer using the measurement results of the positions of the wafer and the die and the offset amount decided in advance will be described below. Note that although signs are inverted depending on the manner the directions of coordinates are defined, the following example complies with the coordinate system shown in the drawings. Let (Wx, Wy) be the position of the wafer 6 measured in step 1002 (the position with respect to the reference point of the bonding apparatus BD), and Wθ be the rotation amount. Also, let (Dx, Dy) be the position of the die 51 with respect to the center of the image captured in step 1003, and Dθ be the rotation amount. Let (Px, Py) be the shift amount generated at the time of bonding, and Pθ be the rotation amount. Also, let (X0, Y0) and θ0 be the offset amounts obtained in step 3008.

If the offset amounts in step 3008 are correctly obtained, Wx=Wy=Wθ=Dx=Dy=Dθ=0. If the same process as in step 3008 is used, bonding can be performed at a high accuracy by driving the bonding stage 45 to (X0, Y0) and θ0 and performing bonding.

If the position of the wafer 6 is deviated from the reference of the bonding stage 45, for example, deviated in the positive direction, this can be corrected by moving the bonding stage 45 by the same amount in the negative direction. Hence, in bonding, the bonding stage 45 is driven to (X0+Wx, Y0+Wy) and (θ0+Wθ).

On the other hand, if the position of the die 51 is deviated from the reference of the bonding head 453, for example, deviated in the positive direction, this can be corrected by moving the bonding stage 45 by the same amount in the negative direction. Hence, to adjust the bonding position, in bonding, the bonding stage 45 is driven to (X0+Wx−Dx, Y0+Wy−Dy), and (θ0+Wθ−Dθ).

Furthermore, as for the shift amount generated at the time of bonding, the bonding position can be adjusted by performing a shift in the same amount. Hence, if deviation occurs in the positive direction, bonding is performed after moving the bonding stage 45 in the reverse direction by the same amount. Hence, in bonding, the bonding stage 45 is driven to (X0+Wx−Dx−Px, Y0+Wy−Dy−Py) and (θ0+Wθ−Dθ−Pθ).

### Fourth Embodiment

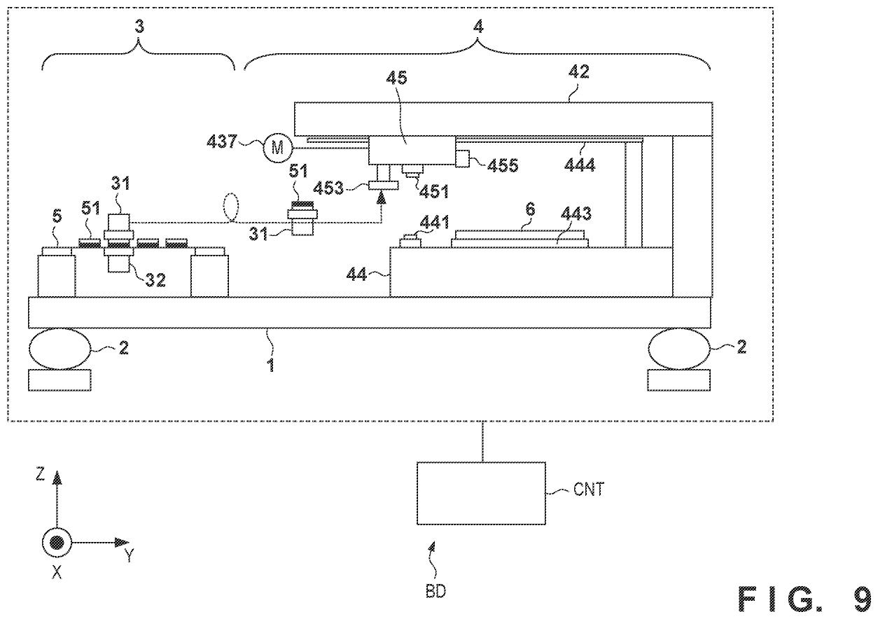

The fourth embodiment will be described below. Matters that are not mentioned as the fourth embodiment can comply with the third embodiment or the first embodiment via the third embodiment. FIG. 9 is a view schematically showing the configuration of a bonding apparatus BD according to the fourth embodiment. In the bonding apparatus BD according to the fourth embodiment, the position of a bonding stage 45 is measured using an encoder.

More specifically, in place of the interferometer 442 and the bar mirror 452 in the bonding apparatus BD according to the third embodiment, an encoder scale 444 and an encoder head 455 are employed in the bonding apparatus BD according to the fourth embodiment. The encoder head 455 is a two-dimensional encoder head mounted on the bonding stage 45. The encoder scale 444 is a two-dimensional encoder scale mounted on a lower base 44. The encoder scale 444 has a two-dimensional scale such that the position of the bonding stage 45 can be measured in the movable range of the bonding stage 45. The encoder head 455 measures the position of the bonding stage 45 concerning the x-axis direction and the y-axis direction.

The encoder scale 444 is made of a material with a low thermal expansion coefficient, and the scale can be drawn at a high position accuracy. In an example, the encoder scale 444 can be formed by drawing the scale on a quartz substrate using the drawing method of a semiconductor lithography process. The bonding stage 45 can have a configuration that combines a coarse motion stage that is driven within a large range, and a fine motion stage that is accurately driven within a small range. In this configuration, the encoder head 455 can be fixed on the fine motion stage to perform accurate positioning. A driving mechanism 437 can form a positioning mechanism that changes the relative position between a wafer chuck 443 (or a wafer 6) serving as a first holder and a bonding head 453 (or a die 51) serving as a second holder. The encoder head 455 and a controller CNT may be understood as the constituent elements of the positioning mechanism.

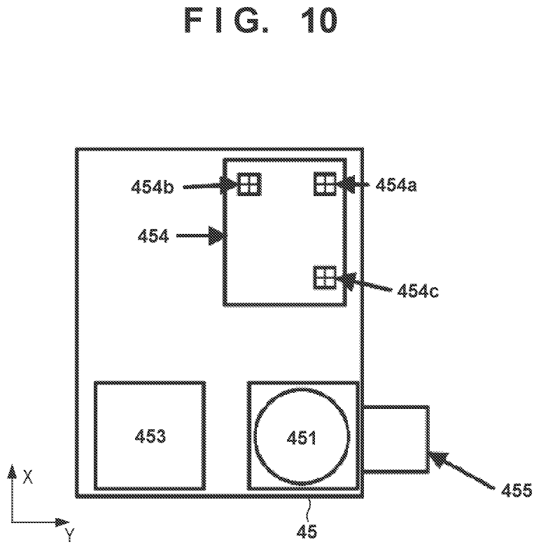

A method of guaranteeing the origin position, the magnification, and the directions (rotations) and orthogonality of the X-axis and the Y-axis of the bonding stage 45 using a reference plate 454 will be described with reference to FIG. 10. A mark 454a is observed by a die observation camera 441, and the output value of the encoder head 455 when the mark 454a is located at the center of the output image of the die observation camera 441 is defined as the origin of the bonding stage 45. Next, a mark 454b is observed by the die observation camera 441, and the direction (rotation) of the Y-axis of the bonding stage 45 and the magnification in the y-axis direction are decided based on the output value of the encoder head 455 when the mark 454b is located at the center of the output image of the die observation camera 441. Next, a mark 454c is observed by the die observation camera 441, and the direction (rotation) of the X-axis of the bonding stage 45 and the magnification in the x-axis direction are decided based on the output value of the encoder head 455 when the mark 454c is located at the center of the output image of the die observation camera 441.

That is, defining the direction from the mark 454b of the reference plate 454 to the mark 454a as the Y-axis of the bonding apparatus BD, and the direction from the mark 454c to the mark 454a as the X-axis of the bonding apparatus BD, the directions and orthogonality of the axes can be calibrated. Also, defining the interval between the mark 454b and the mark 454a as the scale reference of the Y-axis of the bonding apparatus BD and the interval between the mark 454c and the mark 454a as the scale reference of the X-axis of the bonding apparatus BD, calibration can be performed. Since the encoder scale 444 is expanded by heat, and this makes the value measured by the encoder head 455 vary, it is preferable to perform calibration at an arbitrary timing and guarantee the origin position, the magnification, the rotation, and the orthogonality of the bonding stage 45. Note that instead of employing the two-dimensional encoder, a linear encoder may be employed concerning each of the X-axis and the Y-axis.

In place of the above-described configuration, a plurality of encoder heads may be arranged, and, for example, the plurality of encoder heads may selectively be used in accordance with the position of the bonding target portion. This configuration is advantageous in reducing foot print. Alternatively, a pair of encoder heads may be arranged to be symmetrical with respect to the bonding target portion. This configuration is advantageous in improving position measurement accuracy.

The above explanation is related to an example in which calibration is performed by observing the reference plate. Instead, for example, calibration may be performed by an abutting operation to a reference surface, or a calibration mechanism may be provided in the encoder and used as a position measurement device that guarantees an absolute value.

### Fifth Embodiment

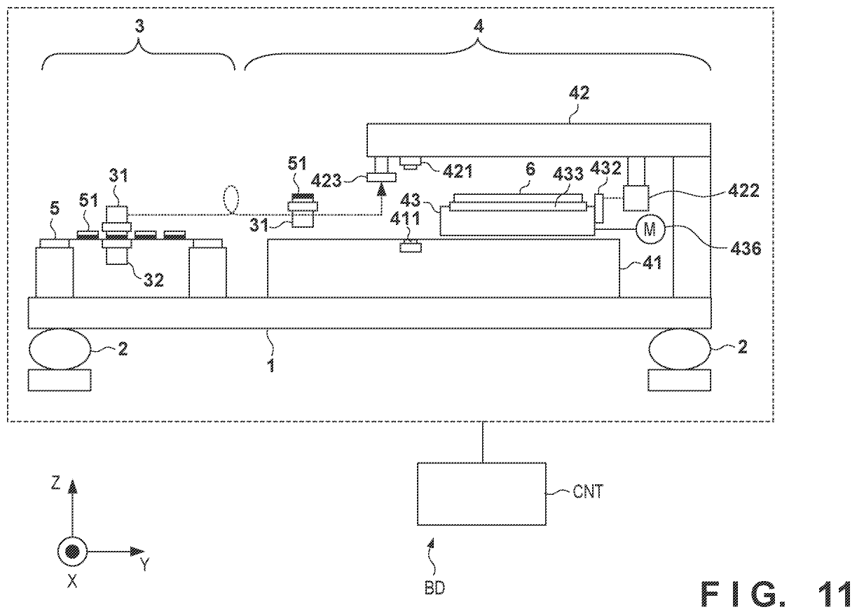

The fifth embodiment will be described below. Matters that are not mentioned as the fifth embodiment can comply with the first embodiment. FIG. 11 is a view schematically showing the configuration of a bonding apparatus BD according to the fifth embodiment. In the bonding apparatus BD according to the first embodiment, a die observation camera 431 is mounted on a wafer stage 43. In the bonding apparatus BD according to the fifth embodiment, a die observation camera 411 is fixed at a position immediately below a bonding head 423. For example, the die observation camera 411 may be fixed to an upper base 42 or a stage base 41. That is, a wafer chuck 433 serving as a first holder and the die observation camera 411 serving as a second camera can be supported by support structures different from each other.

If the die observation camera 411 can displace with respect to the bonding head 423, correction may be performed by measuring the displacement amount. For example, a predetermined mark is arranged on the bonding head 423 and observed by the die observation camera 411, thereby detecting the displacement amount of the die observation camera 411 with respect to the bonding head 423.

### Sixth Embodiment

A method of manufacturing an article (a semiconductor IC element, a liquid crystal element, a MEMS, or the like) using the above-described bonding apparatus BD will be described next. The article is manufactured by a step of preparing a first object, a step of preparing a second object, a step of manufacturing a bonded object by bonding the first object and the second object using the above-described bonding apparatus, and a step of processing the bonded object in another known process. The other known process includes probing, dicing, bonding, packaging, and the like. According to the article manufacturing method, it is possible to manufacture an article of higher quality than before.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-191437, filed Nov. 25, 2021, which is hereby incorporated by reference herein in its entirety.

What is claimed is:

1. A bonding apparatus for bonding a second object to a first object, comprising:
a first holder configured to hold the first object;
a second holder configured to hold the second object;
a positioning mechanism configured to change a relative position between the first holder and the second holder concerning a first direction and a second direction;
a first camera configured to capture the first object;
a second camera configured to capture the second object;
a support configured to support the second holder and the first camera; and
a controller configured to control the positioning mechanism concerning the first direction and the second direction based on an output of the first camera and an output of the second camera such that the second object is positioned to a bonding target portion of the first object.

2. The apparatus according to claim 1, further comprising a support structure configured to support the first holder and the second camera.

3. The apparatus according to claim 2, wherein the support structure includes a first end face on a side of a path to convey the second object to the second holder, and a second end face on an opposite side of the first end face, and the second camera is arranged between the first end face and a virtual plane that passes through a center of the support structure and is parallel to the first end face.

4. The apparatus according to claim 2, wherein the second camera is arranged between the first holder and a predetermined position on the path to convey the second object to the second holder.

5. The apparatus according to claim 3, wherein the support includes a third end face on the side of the path, and a fourth end face on an opposite side of the third end face, and the first camera is arranged between the third end face and a virtual plane that passes through a center of the support and is parallel to the third end face.

6. The apparatus according to claim 2, wherein the positioning mechanism changes the relative position by moving the support structure.

7. The apparatus according to claim 6, further comprising a measurement device configured to measure a position of the support structure,
wherein the controller controls the positioning mechanism such that the support structure is feedback-controlled based on a measurement result of the measurement device.

8. The apparatus according to claim 7, wherein the measurement device includes one of an interferometer and an encoder.

9. The apparatus according to claim 1, wherein the positioning mechanism changes the relative position by moving the support.

10. The apparatus according to claim 9, further comprising a measurement device configured to measure a position of the support,
wherein the controller feedback-controls the positioning mechanism such that the support is positioned based on a measurement result of the measurement device.

11. The apparatus according to claim 10, wherein the measurement device includes one of an interferometer and an encoder.

12. The apparatus according to claim 1, further comprising a support structure configured to support the first holder,
wherein the first holder and the second camera are supported by support structures different from each other.

13. The apparatus according to claim 1, wherein the controller controls the positioning mechanism based on a position of the bonding target portion of the first object specified based on the output of the first camera and a position of the second object specified based on the output of the second camera such that the second object is positioned to the bonding target portion of the first object.

14. The apparatus according to claim 1, wherein the first direction and the second direction are directions along a horizontal plane, and the positioning mechanism changes the relative position concerning not only the first direction and the second direction but also rotation about an axis parallel to a third direction orthogonal to the first direction and the second direction.

15. The apparatus according to claim 1, wherein the controller performs processing of specifying positions of a plurality of bonding target portions of the first object using the first camera and then controls the positioning mechanism such that a plurality of objects including the second object are bonded to the plurality of bonding target portions of the first object, respectively.

16. The apparatus according to claim 15, wherein the controller measures positions of a plurality of measurement target portions of the first object using the first camera, and the number of the plurality of measurement target portions is smaller than the number of the plurality of bonding target portions.

17. A bonding method for bonding a second object to a first object, comprising:
holding the first object by a first holder;
holding the second object by a second holder;
capturing an image of the first object held by the first holder;
capturing an image of the second object held by the second holder;
positioning the second object concerning a first direction and a second direction based on an image captured in the capturing the image of the first object and an image captured in the capturing the image of the second object such that the second object is positioned to a bonding target portion of the first object, and bonding the second object.

18. A bonding method for bonding a second object to a first object, comprising:
holding the first object by a first holder;
holding the second object by a second holder;
deciding positions of a plurality of bonding target portions of the first object based on an image obtained by capturing the first object held by the first holder;
deciding a position of the second object based on an image obtained by capturing the second object held by the second holder; and
positioning and bonding the second object, based on the position of the second object decided in the deciding the position of the second object, to one of the plurality of bonding target portions decided in the deciding the positions of the plurality of bonding target portions,
wherein the deciding the position of the second object and the positioning and bonding the second object are executed for all the plurality of bonding target portions.

19. An article manufacturing method comprising;
preparing a first object;
preparing a second object;
forming a bonded object by bonding the second object to the first object in accordance with a bonding method defined in claim 17; and
processing the bonded object to obtain an article.

20. An article manufacturing method comprising;
preparing a first object;
preparing a second object;
forming a bonded object by bonding the second object to the first object in accordance with a bonding method defined in claim 18; and
processing the bonded object to obtain an article.
